(19) United States
(12) Patent Application Publication
(10) Pub. No.: US 2023/0042772 A1
(43) Pub. Date: Feb. 9, 2023

(54) WIDE GAP SEMICONDUCTOR DEVICE AND METHOD FOR MANUFACTURING WIDE GAP SEMICONDUCTOR DEVICE

(71) Applicant: SHINDENGEN ELECTRIC MANUFACTURING CO., LTD., Tokyo (JP)

(72) Inventors: Yusuke MAEYAMA, Saitama (JP); Shunichi NAKAMURA, Saitama (JP); Jin ONUKI, Saitama (JP)

(73) Assignee: SHINDENGEN ELECTRIC MANUFACTURING CO., LTD., Tokyo (JP)

(21) Appl. No.: 17/790,948

(22) PCT Filed: Mar. 23, 2021
(86) PCT No.: PCT/JP2021/011984

§ 371 Date: Jul. 5, 2022

(30) Foreign Application Priority Data
Mar. 27, 2020 (JP) 2020-057741

(51) Int. Cl. H01L 29/47; H01L 29/16; H01L 29/04; H01L 29/872; H01L 21/04; H01L 29/66

(52) U.S. Cl. CPC H01L 29/47; H01L 29/1608; H01L 29/045; H01L 29/872; H01L 21/0495; H01L 29/6606

(57) ABSTRACT

A wide gap semiconductor device has: a wide gap semiconductor layer; and a metal layer 20 provided on the wide gap semiconductor layer. The metal layer 20 has a single crystal layer 21 in an interface region at an interface with the wide gap semiconductor layer. When it is assumed that a lattice constant, in an equilibrium state, of a metal constituting the metal layer 20 is L, the single crystal layer 21 in the interface region includes a first region in which a lattice constant L1 is smaller than L by 1.5% to 8%.

### TECHNICAL FIELD

The present invention is related to wide gap semiconductor device and method for manufacturing wide gap semiconductor device.

### BACKGROUND ART

Conventionally, a wide gap semiconductor device using silicon carbide or the like has been known (see, for example, Japanese Patent Application Laid-Open No. 2015-56543). In the wide gap semiconductor device, there is a need to lower an on-voltage of a Schottky barrier diode (SBD). Since most of the on-voltage of an SBD is due to a built-in voltage derived from Schottky junction, the on-voltage can be effectively lowered by lowering φB (Schottky barrier).

When n-type silicon carbide, which is a kind of wide gap semiconductor device, is taken as an example, φBn of SiC-SBD is generally controlled by a Schottky electrode, and Ti, Ni, Pt, or the like is used as the Schottky electrode of SiC-SBD. Among them, Ti is known to have the smallest φBn and most of commercially available n-type SiC-SBDs use Ti as the Schottky electrode.

If the conventionally used electrode is changed, an etching step needs to be changed in addition to a deposition step itself. Therefore, there is a demand to lower φB without changing the material of the SBD electrode.

### SUMMARY OF INVENTION

### Problem to be Solved by Invention

The present invention provides a wide gap semiconductor device capable of lowering φB without changing the material of a metal layer that has been conventionally used.

### Means for Solving Problem

### [Concept 1]

A wide gap semiconductor device may comprise:

a wide gap semiconductor layer; and

a metal layer provided on the wide gap semiconductor layer,

wherein the metal layer has a single crystal layer in an interface region at an interface with the wide gap semiconductor layer,

when it is assumed that a lattice constant, in an equilibrium state, of a metal constituting the metal layer is L, the single crystal layer in the interface region includes a first region in which a lattice constant L1 is smaller than L by 1.5% to 8%.

### [Concept 2]

In the wide gap semiconductor device according to concept 1,

the lattice constant L and the lattice constant L1 may be a lattice constant of C-axis.

[Concept 3]

In the wide gap semiconductor device according to concept 1 or 2,

the single crystal layer in the interface region may include the first region at 20% or more.

[Concept 4]

In the wide gap semiconductor device according to any one of concepts 1 to 3,

the single crystal layer in the interface region may include a second region in which the lattice constant L1 is larger than L, and

the first region may occupy a wider region than the second region in the interface region.

### [Concept 5]

In the wide gap semiconductor device according to any one of concepts 1 to 4,

the wide gap semiconductor layer may be a silicon carbide layer having a hexagonal structure,

a crystal structure of the metal layer may have a hexagonal structure, and

the metal of the metal layer may be Ti.

### [Concept 6]

In the wide gap semiconductor device according to concept 5,

the single crystal layer in the interface region may include a first region made of Ti in which the lattice constant L1 is 0.235 nm or less.

### [Concept 7]

In the wide gap semiconductor device according to concept 6,

the single crystal layer in the interface region may include a first region made of Ti, in which the lattice constant L1 is 0.235 nm or less, at 20% or more.

### [Concept 8]

A wide gap semiconductor device according to the present invention may comprise steps of

depositing a Ti layer on a wide gap semiconductor layer; and

heating the Ti layer at 400° C. or lower,

wherein the Ti layer has the single crystal layer in an interface region at an interface between the wide gap semiconductor layer and the Ti layer.

### [Concept 9]

The second aspect of a manufacturing method of a wide gap semiconductor device according to the present invention may comprise steps of

depositing a Ti layer on a wide gap semiconductor layer; and

heating the Ti layer for between 2 minutes and 10 minutes;

wherein the Ti layer may have a single crystal layer in an interface region at an interface between the wide gap semiconductor layer ant the Ti layer.

### [Concept 10]

The third aspect of a manufacturing method of a wide gap semiconductor device according to the present invention may comprise steps of

depositing a Ti layer on a wide gap semiconductor layer at a depositing rate of less than 0.02 nm/s; and

heating the Ti layer;

wherein the Ti layer may have a single crystal layer in an interface region at an interface between the wide gap semiconductor layer ant the Ti layer.

### [Concept 11]

The fourth aspect of a manufacturing method of a wide gap semiconductor device according to the present invention may comprise steps of

depositing a Ti layer on a wide gap semiconductor layer with a degree of vacuum of 5E-4Pa or more; and

heating the Ti layer;

wherein the Ti layer may have a single crystal layer in an interface region at an interface between the wide gap semiconductor layer ant the Ti layer.

### EFFECT OF INVENTION

In the present invention, when an aspect is adopted in which: a single crystal layer is provided in an interface region having a thickness of up to 30 nm from the interface between a wide gap semiconductor layer and a metal layer; and when it is assumed that a lattice constant, in an equilibrium state, of the C-axis of a metal constituting the metal layer is L, the interface region includes first region in which a C-axis lattice constant L1 is smaller than L by 1.5% to 8%, 0 can be lowered.

### BRIEF DESCRIPTION OF DRAWINGS

FIG. 1 is a side sectional view of an n-type silicon carbide semiconductor device that can be used in an embodiment of the present invention.

FIG. 2(a) is a side sectional view showing an aspect in which intervals between constituent atoms are uniform in a single crystal layer, and FIG. 2(b) is a side sectional view showing an aspect in which intervals between constituent atoms are not uniform in a single crystal layer.

FIG. 3 is a graph showing a relationship between a C-axis lattice constant L1 in a single crystal layer containing Ti and a cumulative probability plot in an aspect in which annealing temperatures of Ti are different.

FIG. 4 is a graph showing a relationship between the C-axis lattice constant L1 in the single crystal layer containing Ti and φBn (eV) in an n-type silicon carbide device.

FIG. 5 is a graph showing a relationship between the C-axis lattice constant L1 in the single crystal layer containing Ti and Ef (eV) in a silicon carbide device, the relationship being obtained by theoretical calculations.

FIG. 6 is a graph showing a relationship between the C-axis lattice constant L1 in the single crystal layer containing Ti and an n value in the silicon carbide device.

FIG. 7 is a graph showing a relationship between an annealing time of a metal electrode containing Ti at 450° C. and φBn (eV) in a manufactured n-type silicon carbide device.

FIG. 8 is a graph showing a relationship between a Ti deposition rate and φBn (eV) in the manufactured n-type silicon carbide device.

FIG. 9 are images respectively showing a cross-sectional TEM image at 600,000× magnification, a cross-sectional TEM image at 3,000,000× magnification, and a selected-area electron diffraction pattern.

### EMBODIMENT OF THE INVENTION

### Embodiment

<<Configuration>>

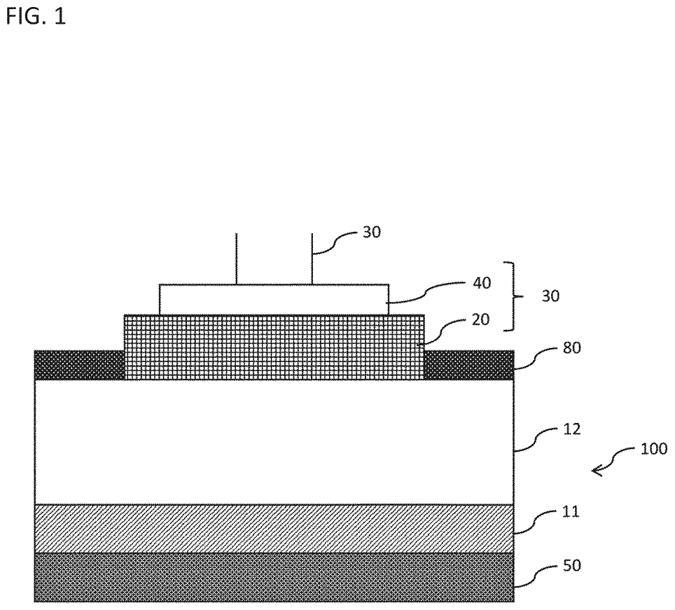

In the present embodiment, “one side” means a front surface side that is the upper side in FIG. 1, and “the other side” means a back surface side that is the lower side in FIG. 1.

The present embodiment will be described by using an n-type silicon carbide semiconductor device (hereinafter, simply referred to as a “silicon carbide semiconductor device”) as an example of a wide gap semiconductor device, but the present invention is not limited thereto. A special silicon carbide substrate may be adopted in which a single crystal silicon carbide layer is formed on polycrystalline silicon carbide. As the wide gap semiconductor, gallium nitride, gallium oxide, diamond, or the like may be used other than silicon carbide.

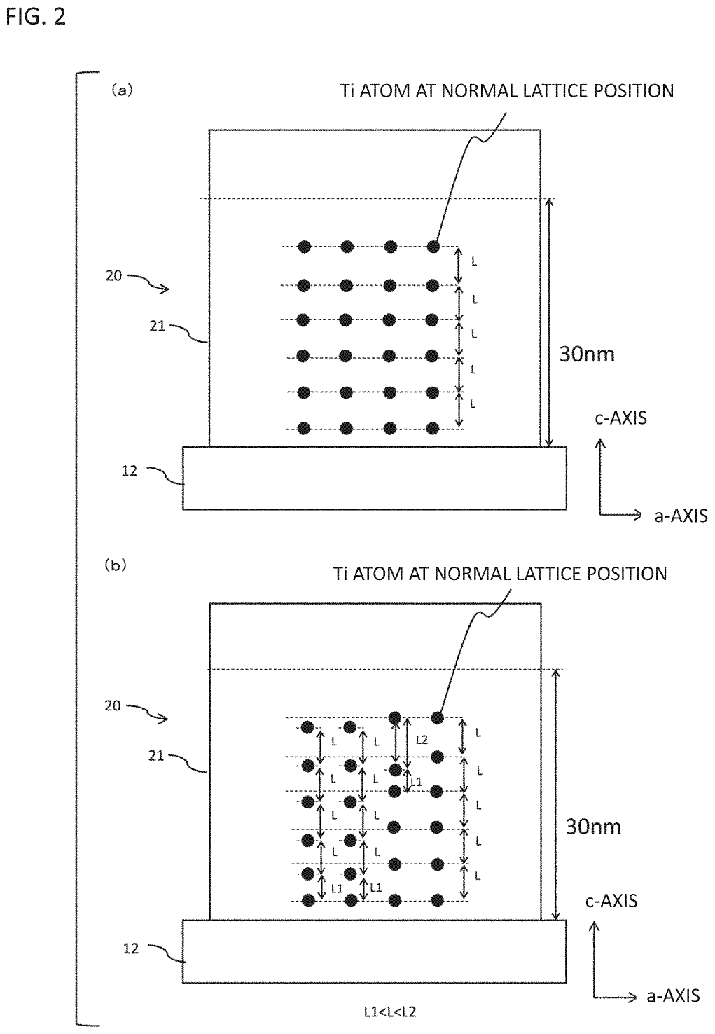

As shown in FIG. 1, the silicon carbide semiconductor device may have a silicon carbide substrate 11, a silicon carbide layer 12 provided on the one side (front surface side) of the silicon carbide substrate 11, and a metal electrode 20 that is a metal layer provided on the one side of the silicon carbide layer 12 to function as a front surface electrode. Note that as an example in the aspect shown in FIG. 1, the silicon carbide layer 12 is directly provided on the silicon carbide substrate 11, and the metal electrode 20 is directly provided on the silicon carbide layer 12. As shown in FIGS. 2(a) and 2(b), the metal electrode 20 may have a single crystal layer 21 in an interface region at an interface with the silicon carbide layer 12. When it is assumed that a lattice constant, in an equilibrium state, of the C-axis of a metal constituting the metal electrode 20 is L, the single crystal layer 21 in the interface region may include first region in which a C-axis lattice constant is smaller than L by 1.5% to 8% (each having L1). The single crystal layer 21 may be formed by heteroepitaxial growth.

In the present embodiment, the “interface region” in the metal electrode 20 means a region in the range of 30 nm from the interface between the metal electrode 20 and the silicon carbide layer 12, in the thickness direction, toward the metal electrode 20 (the one side). On the further one side of the interface region of the metal electrode 20, the metal electrode 20 may have a single crystal structure, a polycrystalline structure, or an amorphous structure.

As shown in FIG. 1, the metal electrode 20 may be provided with a connection electrode 40. In addition, the connection electrode 40 may be provided with a connection part 30. The connection part 30 may be a wire or a connecting body.

The connection electrode 40 may contain aluminum, an aluminum alloy containing silicon, an aluminum alloy containing copper, titanium, or the like, or may include a laminated film of an aluminum alloy containing silicon, an aluminum alloy containing copper, or aluminum and titanium. Without being limited thereto, the connection electrode 40 may contain another metal such as copper, gold, or nickel.

A back surface electrode 50 may be provided on the other side (back surface side) of the silicon carbide semiconductor substrate 11. The back surface electrode 50 may contain nickel, titanium, or the like. An insulating layer 80, containing oxide or the like, may be provided in a region that is located on the one side (front surface side) of the silicon carbide layer 12 and in which a first electrode part 30 is not provided.

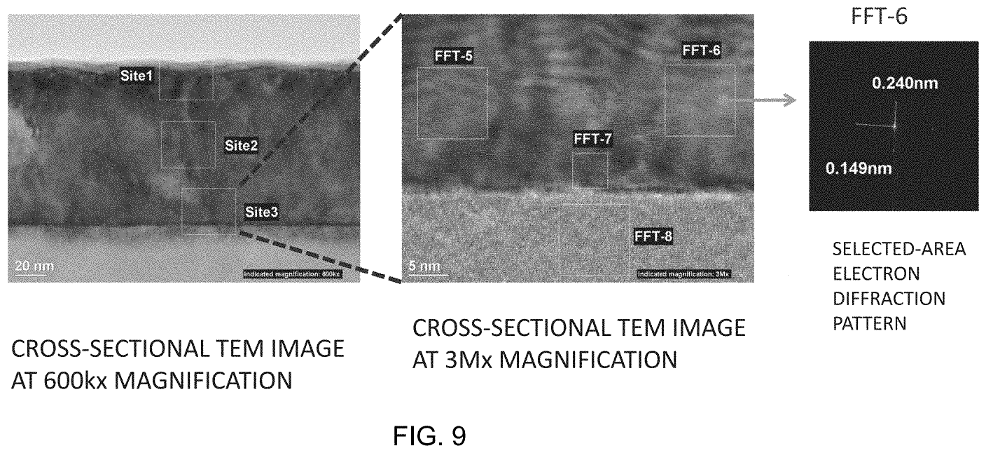

The single crystal layer 21 in the interface region may include the first region, in which the C-axis lattice constant is L1, at 20% or more, or may include the first region at 30% or more thereof. In the present embodiment, “containing the first region at A% or more” means that when one image is captured with a TEM, the first region in which the lattice constant is L1 can be confirmed at A% or more in all region (see FIG. 9). However, whether or not the first region is at 20% or more included may be confirmed by capturing a plurality of images (e.g., 2 to 10 images) with a TEM and using measurement results in the plurality of images.

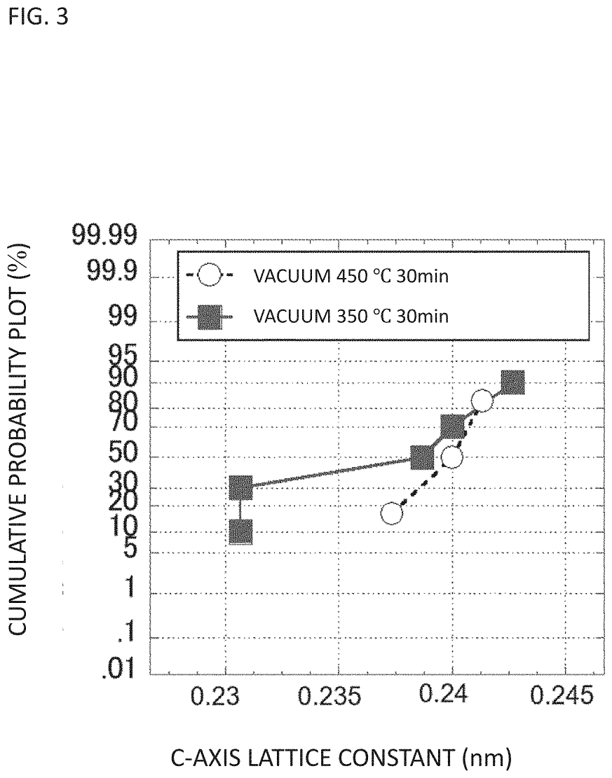

When the metal contains Ti, the lattice constant L in an equilibrium state is 0.24 nm. Therefore, the fact that the C-axis lattice constant L1 is smaller than L by 1.5% to 8% means that the C-axis lattice constant L1 falls within the range of 0.2208 nm to 0.2364 nm. FIG. 3 is a graph in which the cumulative probabilities of the C-axis lattice constant L1 are plotted. The graph shows that when annealing is performed at 450° C. for 30 minutes in a vacuum state of 1E-4 Pa (1×10⁻⁴ Pa), the probability that the C-axis lattice constant L1 is about 0.236 nm or less is less than 20%, whereas when annealing is performed at 350° C. for 30 minutes in a vacuum state of 1E-4 Pa, the probability that the C-axis lattice constant L1 is about 0.233 nm or less is 30%. TEM is used for the measurement, and the result is obtained by cross-sectional diffraction images (see FIG. 9). FIG. 9 shows a cross-sectional TEM image at 600,000× magnification, a cross-sectional TEM image at 3,000,000× magnification, and a selected-area electron diffraction pattern. The lattice constant L1 of the single crystal can be measured from the selected-area electron diffraction pattern.

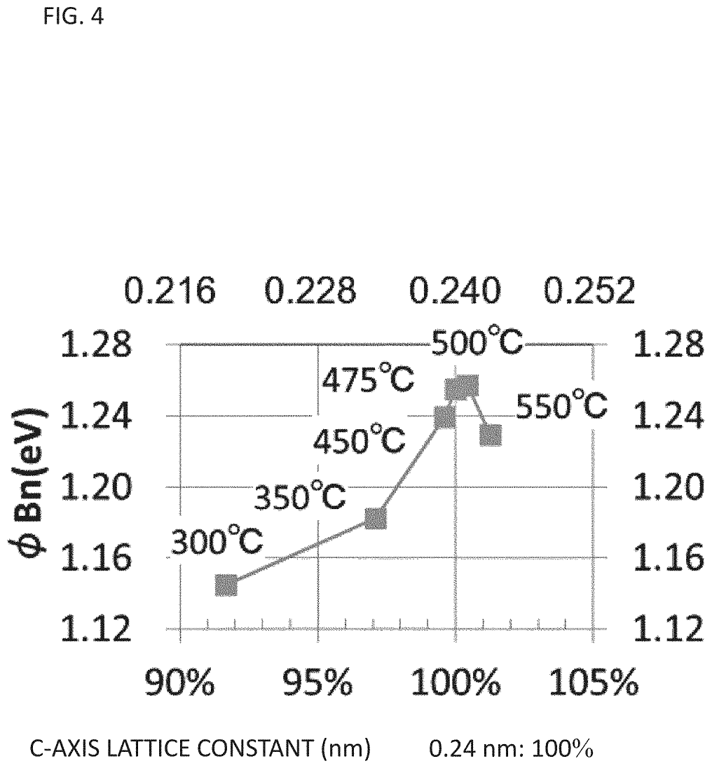

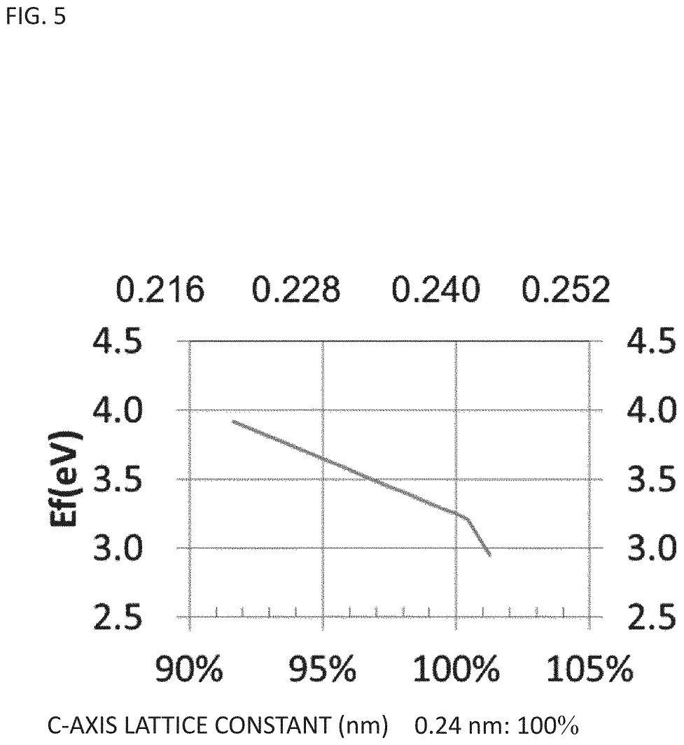

As confirmed by the inventors, it is found, as shown in FIG. 4, that φBn (eV) decreases as the C-axis lattice constant Ll decreases. It has also been confirmed, as shown in FIG. 5, that as a result of verification by first-principles calculations, the Fermi level (Ef) changes in a direction of lowering φBn by reducing the lattice constant. The value (C-axis lattice constant) on the horizontal axis shown in FIG. 4 represents a lattice constant when the cumulative probability is 30%. Note that there is the relationship that the larger Ef (eV), the smaller φBn (eV).

The crystal structure of the silicon carbide layer 12 may have a hexagonal structure, or may have a hexagonal close-packed structure. The crystal structure of the metal electrode 20 may have a hexagonal structure, or may have a hexagonal close-packed structure. The metal of the metal electrode 20 in the interface region may contain Ti. However, without being limited thereto, the metal of the metal electrode 20 in the interface region may include a metal containing Ti as a main component, or may include Ni, Pt, Mo, a metal containing Ni as a main component, a metal containing Pt as a main component, or a metal containing Mo as a main component. However, from the viewpoint that φBn can be lowered to a small value, it is advantageous to use the metal electrode 20 containing Ti or the metal electrode 20 including a metal containing Ti as a main component, and it is particularly advantageous to use the metal electrode 20 containing Ti. Note that the term “main component” means that it occupies 50% or more in mass percent, and the metal containing Ti as a main component means a metal containing 50 mass% or more of Ti.

Even when the metal of the metal electrode 20 in the interface region contains Ti, a metal layer containing Ni, Al, or the like may be provided on the one side of the electrode containing Ti.

The single crystal layer 21 in the interface region may include first region containing Ti in which the C-axis lattice constant L1 is 0.235 nm or less.

Next, an example of a manufacturing method will be described. In the following manufacturing example, an aspect will be described in which Ti is used as the metal electrode 20.

### Manufacturing Example 1

A Ti layer is deposited on a substrate in which the silicon carbide layer 12 is provided on the silicon carbide substrate 11. For the deposition of the Ti layer, electron beam deposition may be used, or sputtering may be used. A deposition rate is, for example, 0.1 to 0.3 nm/s (e.g., 0.12 nm/s), and the degree of vacuum at the time of the deposition of the Ti layer is, for example, 1E-4 Pa to 1E-5 Pa (e.g., 1E-4 Pa).

Next, the substrate provided with the Ti layer is annealed (heated) at 400° C. or lower. The substrate provided with the Ti layer is annealed, for example, at 350° C. for 30 minutes to 60 minutes (e.g., 30 minutes). As a result, the metal electrode 20 including the Ti layer is generated.

Immediately after the Ti layer is deposited on the silicon carbide layer 12, vacancies are included in the Ti layer in the interface region between the silicon carbide layer 12 and the Ti layer. When the Ti layer is annealed, crystallized of Ti proceeds while the vacancies are diffused outward. It is considered that when the annealing temperature is set to 450° C. to 500° C., perfect crystal Ti (equilibrium state) is obtained, and the C-axis lattice constant increases (see FIG. 2(a)). As a result, φBn is saturated at a large value.

On the other hand, when the annealing is performed at 400° C. or lower (e.g., 350° C.) as in the present embodiment, the vacancies in the Ti layer are suppressed from being diffused outward, so that a state of including many vacancies can be realized. As a result, it is considered that stress is generated in the Ti layer, and the intervals between the Ti atoms tend to be uneven (see FIG. 2(b)). Then, region (first region) in which a lattice constant is smaller than that at the time of complete crystallization and region (second region) in which a lattice constant is larger than that therein are both generated. When the number of the region (first region) in which a lattice constant is small is larger than the number of the region (second region) in which a lattice constant is large, φBn can be lowered.

Here, FIGS. 2 are simplified views for understanding the above description. In a region including the atoms arranged on the right-most in FIG. 2(b), the interatomic distances between the arranged constituent atoms are constant L, and the average lattice constant in the C-axis direction is L. In a region including the atoms arranged second from the right in FIG. 2(b), the interatomic distances between the arranged constituent atoms are uneven by being divided into L1, L2, and L. L1 is smaller than L. L2 is larger than L. However, since the number of the regions, in each of which the interatomic distances are L1, and the number of the regions, in each of which the interatomic distances are L2, are equal, the average lattice constant of the lattice constants in the C-axis direction is L in this region. In a region including the atoms arranged third from the right in FIG. 2(b), the interatomic distances between the arranged constituent atoms are uneven by being divided into L1 and L. L1 is smaller than L. Therefore, the average lattice constant of the lattice constants in the C-axis direction is smaller than L in this region. In a region including the atoms arranged fourth from the right in FIG. 2(b), the interatomic distances between the arranged constituent atoms are uneven by being divided into L1 and L. L1 is smaller than L. Therefore, the average lattice constant of the lattice constants in the C-axis direction is smaller than L in this region.

As a result, when the aspect of FIG. 2(b) is viewed as a whole, the average lattice constant in the C-axis direction is smaller than L. FIG. 3 can be said to show an actual measurement result supporting this. FIG. 3 shows that when annealing is performed at 400° C. or lower (here, 350° C.), region (second region) in which the lattice constant in the C-axis direction is large exist (a plot exists at a location where the C-axis lattice constant is about 0.2425 nm), but region (first region) in which the lattice constant is small also exist (a plot also exists at a location where the C-axis lattice constant is about 0.2306 nm). And, it is shown that the number of the region (second region), in which the lattice constant is large, is smaller than the number of region (first region) in which the lattice constant is small. That is, the lattice constant in the C-axis direction decreases on average. As a result, φBn decreases as described above.

It can also be confirmed that the lattice constant decreases by the fact that when one image is captured with TEM, the first region occupies a wider region than the second region. Alternatively, it may also be confirmed that the first region occupies a wider region than the second region by capturing a plurality of images (e.g., 2 to 10 images) with TEM and using measurement results in the plurality of images.

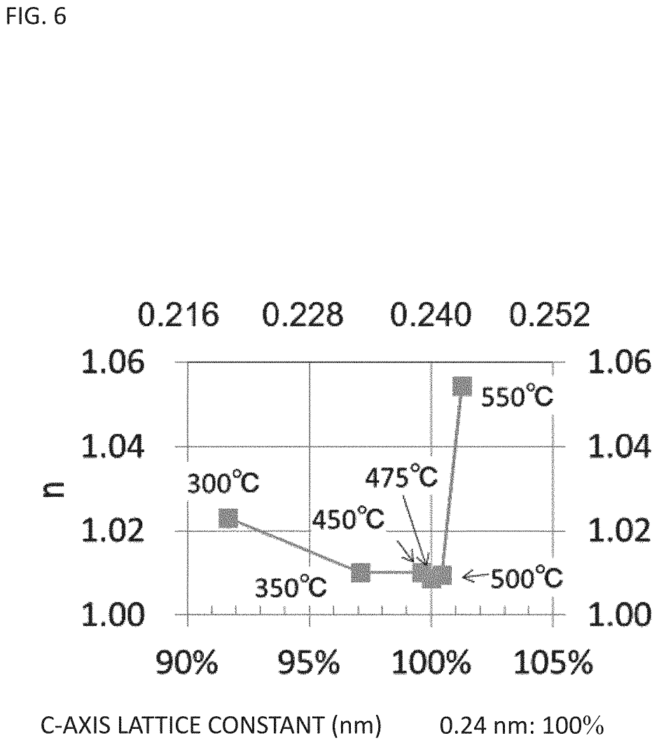

Note that as shown in FIG. 4, it could be confirmed that φBn also decreased when the annealing was performed at 550° C. or higher, while as shown in FIG. 6, when the annealing was performed at 550° C. or higher, the n value (ideal factor) was deteriorated. This is considered to be because a chemical reaction occurs between the Ti layer and the silicon carbide layer 12. The value (C-axis lattice constant) on the horizontal axis shown in FIG. 6 also represents a lattice constant when the cumulative probability is 30%, similarly to FIG. 4.

### Manufacturing Example 2

Next, another manufacturing example different from the above will be described. Similarly to the manufacturing example 1, a Ti layer is deposited on a substrate in which the silicon carbide layer 12 is provided on the silicon carbide substrate 11. For the deposition of the Ti layer, electron beam deposition may be used, or sputtering may be used. A deposition rate is, for example, 0.1 to 0.3 nm/s (e.g., 0.12 nm/s), and the degree of vacuum at the time of the deposition of the Ti layer is, for example, 1E-4 Pa to 1E-5 Pa (e.g., 1E-4 Pa).

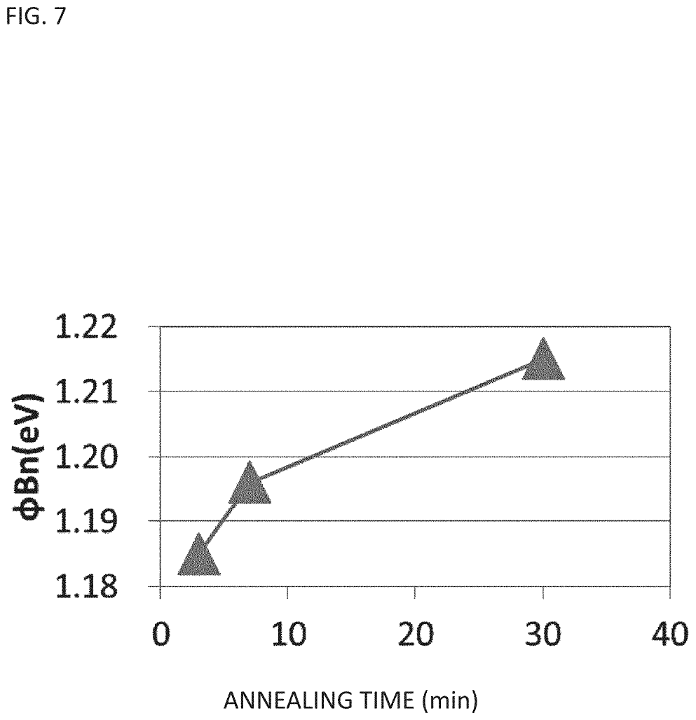

Next, the substrate provided with the Ti layer is annealed (heated) at 450° C. to 500° C. The substrate provided with the Ti layer is annealed, for example, at 450° C. for between 2 minutes and 10 minutes (inclusive) (e.g., 8 minutes). FIG. 7 is a graph showing a relationship between an annealing time when annealing is performed at 450° C. and φBn (eV), and it can be confirmed that φBn (eV) decreases when the annealing time is short.

As described above, immediately after the Ti layer is deposited on the silicon carbide layer 12, a state is created at the interface between the silicon carbide layer 12 and the Ti layer, in which vacancies are included in the Ti layer. When the Ti layer is annealed, crystallized of Ti proceeds while the vacancies in the Ti layer are diffused outward. In this respect, even when annealing is performed at 450 to 500° C., the vacancies in the Ti layer are suppressed from being diffused outward by shortening the annealing time. Therefore, a state in which many vacancies are included in the Ti layer can be realized, and region, in which a lattice constant is smaller than that at the time of complete crystallization, can be formed by generating stress. As a result, φBn can be lowered.

### Manufacturing Example 3

Next, a manufacturing example 3 different from the above manufacturing examples 1 and 2 will be described.

Also in the manufacturing example 3, a Ti layer is deposited on a substrate in which the silicon carbide layer 12 is provided on the silicon carbide substrate 11, similarly to the manufacturing examples 1 and 2. For the deposition of the Ti layer, electron beam deposition may be used, or sputtering may be used. However, a deposition rate in the manufacturing example 3 is set to be less than 0.02 nm/s. For example, the deposition rate may be, for example, 0.01 nm/s or less (e.g., 0.01 nm/s), and the degree of vacuum at the time of the deposition of the Ti layer is, for example, 1E-4 Pa to 1E-5 Pa (e.g., 1E-4 Pa).

Next, the substrate provided with the Ti layer is annealed (heated) at 450 to 500° C. The substrate provided with the Ti layer is annealed, for example, at 450° C. for 30 minutes to 60 minutes (e.g., 30 minutes).

By reducing the deposition rate as in the present manufacturing example, the probability that molecules, atoms, ions, and the like other than Ti fly to the front surface of the silicon carbide layer 12 at the time of the deposition relatively increases. Therefore, a state is created in which more vacancies are included in the Ti layer at the interface between the Ti layer and the silicon carbide layer 12. Therefore, even when the annealing temperature is set to 450° C. to 500° C. and the annealing time is set to 30 minutes, more vacancies remain in the Ti layer. Therefore, region in which a lattice constant is smaller than that at the time of complete crystallization can be formed by generating stress, and 0 can be lowered.

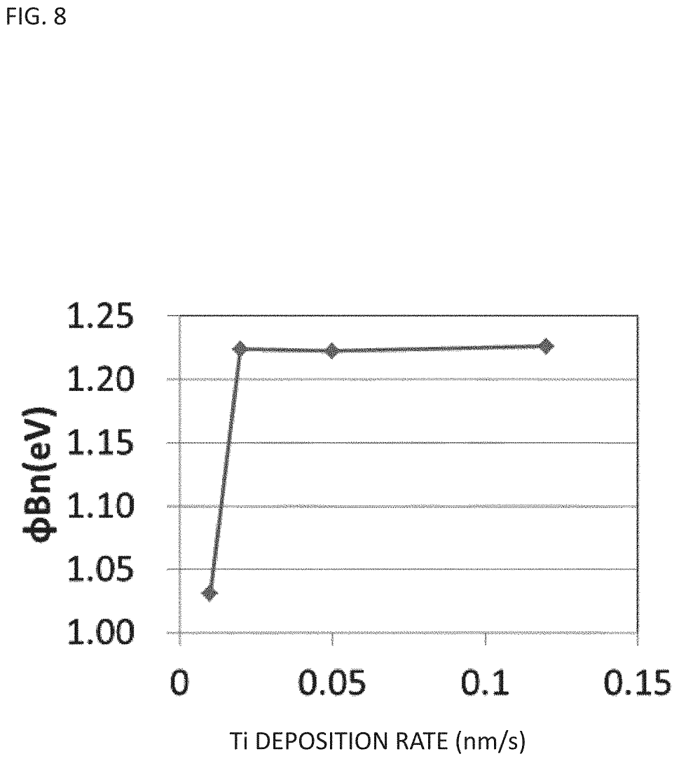

The results of changing, by the inventors of the present application, the deposition rate under conditions in which the annealing is performed at 450° C. for 30 minutes are as shown in Table 1 below. These results are shown in FIG. 8.

TABLE 1

| Degree of vacuum (Pa) | Deposition rate (nm/s) | φBn (eV) |
|---|---|---|
| 1.00E−04 | 0.01 | 1.031 |
| 1.00E−04 | 0.02 | 1.224 |
| 1.00E−04 | 0.05 | 1.223 |
| 1.00E−04 | 0.12 | 1.226 |

### Manufacturing Example 4

Next, a manufacturing example 4 different from the manufacturing examples 1 to 3 will be described.

Also in the manufacturing example 4, a Ti layer is deposited on a substrate in which the silicon carbide layer 12 is provided on the silicon carbide substrate 11, similarly to the manufacturing examples 1 to 3. For the deposition of the Ti layer, electron beam deposition may be used, or sputtering may be used. However, the degree of vacuum at the time of the deposition in the manufacturing example 4 is set to 5E-4 Pa or more. For example, a deposition rate is, for example, 0.1 to 0.3 nm/s (e.g., 0.12 nm/s), and the degree of vacuum at the time of the deposition of the Ti layer is 5E-4 Pa or more (e.g., 9.3E-4 Pa). If the degree of vacuum is excessively increased, various problems occur, and thus the upper limit value is 1E-2 Pa.

Next, the substrate provided with the Ti layer is annealed (heated) at 450 to 500° C. The substrate provided with the Ti layer is annealed, for example, at 450° C. for 30 minutes to 60 minutes (e.g., 30 minutes).

By increasing the degree of vacuum as in the present manufacturing example, the probability that molecules, atoms, ions, and the like other than Ti fly to the front surface of the silicon carbide layer 12 at the time of the deposition relatively increases. Therefore, a state is created in which more vacancies are included in the Ti layer at the interface between the Ti layer and the silicon carbide layer 12. Therefore, even when the annealing temperature is set to 450 to 500° C. and the annealing time is set to 30 minutes, more vacancies remain in the Ti layer. Therefore, region in which a lattice constant is smaller than that at the time of complete crystallization can be formed by generating stress, and φBn can be lowered.

The results of the inventors of the present application setting the degree of vacuum to 9.3E-4 Pa under conditions in which the annealing is performed at 450° C. for 30 minutes are as shown in Table 2 below, and it could be confirmed that φBn could be lowered.

TABLE 2

| Degree of vacuum (Pa) | Deposition rate (nm/s) | φBn (eV) |
|---|---|---|
| 9.30E−04 | 0.12 | 1.18 |

<<Effects>>

Next, effects of the present embodiment having the above-described configuration will be described. Note that all aspects described in the “effects” can be adopted in the above configuration.

In the present embodiment, when an aspect is adopted in which the single crystal layer 21 in the interface region of the metal electrode 20 includes first region in which the C-axis lattice constant L1 is smaller than the lattice constant L in an equilibrium state by 1.5% to 8%, φBn can be lowered without changing the material of the metal electrode 20.

When the single crystal layer 21 in the interface region includes the first region, in which the C-axis lattice constant is L1 (value smaller than L by 1.5% to 8%), at 20% or more, φBn can be lowered more reliably. In addition, when the single crystal layer 21 in the interface region includes the first region, in which the C-axis lattice constant is L1 (value smaller than L by 1.5% to 8%), at 30% or more, φBn can be lowered even more reliably (see FIG. 3 and FIG. 4).

When the metal electrode 20 in the interface region contains hexagonal Ti and the silicon carbide layer 12 in contact with the Ti has a hexagonal structure, φBn can be lowered more reliably.

When the single crystal layer 21 in the interface region contains Ti, the originally low φBn can be further lowered, and when the single crystal layer includes the first region containing Ti in which the C-axis lattice constant L1 is 0.235 nm or less, φBn can be lowered more reliably.

The description of the embodiments and the disclosure of the drawings described above are merely examples for describing the invention described in the claims, and the invention described in the claims is not limited by the description of the embodiments or the disclosure of the drawings described above. In addition, the description of the claims as originally filed is merely an example, and the description of the claims can be appropriately changed based on the description of the specification, the drawings, and the like.

### REFERENCE SIGNS LIST

12 silicon carbide layer (wide gap semiconductor layer)

20 metal electrode

21 single crystal layer

1. A wide gap semiconductor device comprising:
a wide gap semiconductor layer; and
a metal layer provided on the wide gap semiconductor layer,
wherein the metal layer has a single crystal layer in an interface region at an interface with the wide gap semiconductor layer,
when it is assumed that a lattice constant, in an equilibrium state, of a metal constituting the metal layer is L, the single crystal layer in the interface region includes a first region in which a lattice constant L1 is smaller than L by 1.5% to 8%.

2. The wide gap semiconductor device according to claim 1,
wherein the lattice constant L and the lattice constant L1 are a lattice constant of C-axis.

3. The wide gap semiconductor device according to claim 1,
wherein the single crystal layer in the interface region includes the first region at 20% or more.

4. The wide gap semiconductor device according to claim 1,
wherein the single crystal layer in the interface region includes a second region in which the lattice constant L1 is larger than L, and
wherein the first region occupies a wider region than the second region in the interface region.

5. The wide gap semiconductor device according to claim 1,
wherein the wide gap semiconductor layer is a silicon carbide layer having a hexagonal structure,
wherein a crystal structure of the metal layer has a hexagonal structure, and
wherein the metal of the metal layer is Ti.

6. The wide gap semiconductor device according to claim 1,
wherein the single crystal layer in the interface region includes a first region made of Ti in which the lattice constant L1 is 0.235 nm or less.

7. The wide gap semiconductor device according to claim 6,
wherein the single crystal layer in the interface region includes a first region made of Ti, in which the lattice constant L1 is 0.235 nm or less, at 20% or more.

8. A method for manufacturing wide gap semiconductor device comprising steps of
depositing a Ti layer on a wide gap semiconductor layer; and
heating the Ti layer at 400° C. or lower,
wherein the Ti layer has the single crystal layer in an interface region at an interface between the wide gap semiconductor layer and the Ti layer.
